(19) United States
(12) Patent Application Publication
(10) Pub. No.: US 2009/0139750 A1
(43) Pub. Date: Jun. 4, 2009

(54) Printed wiring board and printed circuit board unit and electronic apparatus

(75) Inventor: Ryo Kanai, Kawasaki (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, Kawasaki (JP)

(21) Appl. No.: 12/318,656

(22) Filed: Jan. 5, 2009

Related U.S. Application Data
(63) Continuation of application No. PCT/JP2006/313408, filed on Jul. 5, 2006.

(51) Int. Cl. H05K 1/14

(52) U.S. Cl. 174/254

(57) ABSTRACT

A printed wiring board has a rigid insulating layer. A first substrate is partly overlaid on the front surface of the rigid insulating layer. The first substrate has a free end located outside the contour of the rigid insulating layer. A second substrate is partly overlaid on the back surface of the rigid insulating layer. The second substrate has a free end located outside the contour of the rigid insulating layer. The second substrate has the front surface opposed to the back surface of the first substrate. A component or components can thus be disposed on the back surface of the first substrate and the front surface of the second substrate outside the contour of the rigid insulating layer. The mounting area for components can be increased.

### CROSS-REFERENCE TO RELATED APPLICATION

This application is a continuing application, filed under 35 U.S.C. §111(a), of International Application PCT/JP2006/313408, filed Jul. 5, 2006, the contents of which are incorporated herein by reference.

### BACKGROUND

1. Field

The present invention relates to a printed circuit board unit incorporated in an electronic apparatus, for example.

2. Description of the Prior Art

A printed circuit board unit includes a pair of rigid substrates, and a flexible printed wiring board connecting the rigid substrates to each other, as disclosed in Japanese Patent Application Publication No. 5-335714, for example. The flexible printed wiring board is folded several times between the rigid substrates. The flexible printed wiring board in this manner provides first, second and third layers. Electronic components can be mounted on the front and back surfaces of the second layer. The first and third layers serve to electrically insulate the electronic components on the second layer from electronic components mounted on the front and back surfaces of the rigid substrates.

An electronic component cannot be mounted on the folded section of the flexible printed wiring board and the first and third layers in the printed circuit board unit. In addition, a connector is located on the surface of the rigid substrate for connection of the flexible printed wiring board. The connector occupies a predetermined space on the surface of the rigid substrate. It is thus hard to ensure a sufficient mounting space for an electronic component in the printed circuit board unit.

### SUMMARY

It is accordingly an object of the present invention to provide a printed wiring board, a printed circuit board unit and an electronic apparatus, all contributing to enlargement of a mounting area for components.

According to a first aspect of the present invention, there is provided a printed wiring board comprising: a rigid insulating layer; a first substrate partly overlaid on the front surface of the rigid insulating layer, the first substrate having a free end located outside the contour of the rigid insulating layer; and a second substrate partly overlaid on the back surface of the rigid insulating layer, the second substrate having a free end located outside the contour of the rigid insulating layer, the second substrate having the front surface opposed to the back surface of the first substrate.

The printed wiring board allows establishment of a rigid substrate based on a combination of the rigid insulating layer and the first and second substrates. The first and second substrates have the free ends located outside the contour of the rigid insulating layer. The rigid insulating layer serves to provide an interval between the first and second substrates. A component or components can thus be disposed on the back surface of the first substrate and the front surface of the second substrate outside the contour of the rigid insulating layer. The mounting area for components can be increased.

At least the first substrate may be movable or changeable in its attitude relative to the second substrate in the printed wiring board. Since the first substrate is movable relative to the second substrate, the first substrate can be turned over outside the contour of the rigid insulating layer so that components are mounted thereon, for example. The back surface of the first substrate and the front surface of the second substrate are thus exposed. Components can be mounted on the back surface of the first substrate and the front surface of the second substrate in a relatively facilitated manner. Likewise, the components can be removed from the back surface of the first substrate and the front surface of the second substrate in a relatively facilitated manner.

According to a second aspect of the present invention, there is provided a printed circuit board unit comprising: a rigid insulating layer; a first substrate partly overlaid on the front surface of the rigid insulating layer, the first substrate having a free end located outside the contour of the rigid insulating layer; a second substrate partly overlaid on the back surface of the rigid insulating layer, the second substrate having a free end located outside the contour of the rigid insulating layer, the second substrate having the front surface opposed to the back surface of the first substrate; and a component mounted on at least one of the back surface of the first substrate and the front surface of the second substrate.

The printed circuit board unit allows establishment of a rigid substrate based on a combination of the rigid insulating layer and the first and second substrates. The first and second substrates have the free ends located outside the contour of the rigid insulating layer. The rigid insulating layer serves to provide an interval between the first and second substrates. A component or components can be disposed on the back surface of the first substrate and the front surface of the second substrate. The mounting area for components can be increased. At least the first substrate may be movable or changeable in its attitude relative to the second substrate in the same manner as described above. The printed circuit board unit may be incorporated in an electronic apparatus, for example.

Additional objects and advantages of the invention will be set forth in part in the description which follows and, in part will be obvious from the description, or may be learned by practice of the present invention. The object and advantages of the invention will be realized and attained by means of the elements and combinations particularly pointed out in the appended claims. It is to be understood that both the foregoing general description and the following detailed description are exemplary and explanatory only and are not restrictive of the invention, as claimed.

### BRIEF DESCRIPTION OF THE DRAWINGS

The above and other objects, features and advantages of the present invention will become apparent from the following description of the preferred embodiments in conjunction with the accompanying drawings, wherein:

FIG. 1 is a perspective view schematically illustrating a mobile phone terminal as an example of an electronic apparatus according to the present invention;

FIG. 2 is a perspective view schematically illustrating a printed circuit board unit according to an example of the present invention;

FIG. 3 is a sectional view taken along the line 3-3 in FIG. 2;

FIG. 4 is a view schematically illustrating the process of overlaying first and second flexible printed wiring boards on rigid insulating layers;

FIG. 5 is a view schematically illustrating the process of turning over the first flexible printed wiring board;

FIG. 6 is a view schematically illustrating the first and second flexible printed wiring boards with electronic components mounted thereon;

FIG. 7 is a view schematically illustrating a printed circuit board unit according to another example of the present invention; and

FIG. 8 is a view schematically illustrating a printed circuit board unit according to another example of the present invention.

### DESCRIPTION OF THE PREFERRED EMBODIMENTS

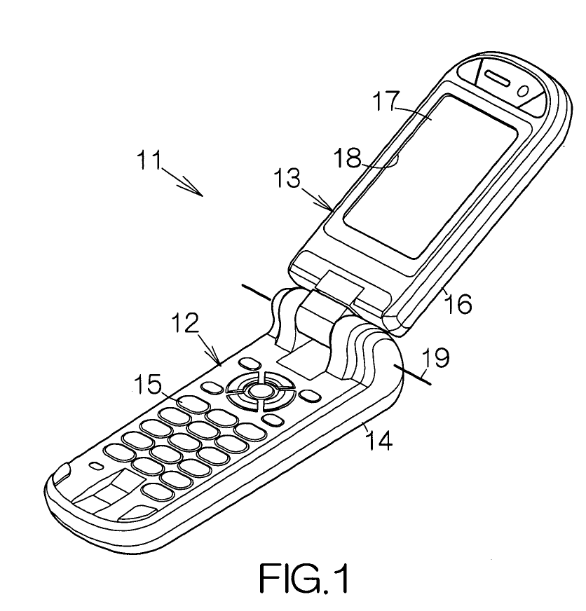

FIG. 1 schematically illustrates a cellular or mobile phone terminal 11 of the clamshell type as an example of an electronic apparatus. The mobile phone terminal 11 includes a main apparatus 12 and a display unit 13. The main apparatus 12 includes a main body enclosure 14 serving as a first enclosure. A printed circuit board unit is incorporated in the main body enclosure 14, as described later in detail. The printed circuit board unit includes processing circuits, such as a central processing unit (CPU) and a memory.

Keypads 15, such as an on-hook keypad, an off-hook keypad, numeric keypads, and the like, are embedded in the flat front surface of the main apparatus 12. The CPU executes various processing in response to the manipulation of the keypads 15. The main body enclosure 14 may be molded from a reinforced resin material, for example.

The display unit 13 includes a display enclosure 16 serving as a second enclosure. A flat display panel unit, such as a liquid crystal display (LCD) panel unit 17, is incorporated in the display enclosure 16. A window opening 18 is defined in the flat front surface of the display enclosure 16. The screen of the LCD panel unit 17 is placed within the window opening 18. Various texts and graphics are displayed on the screen of the LCD panel unit 17 in response to the operation of the CPU. The display enclosure 16 may be molded from a reinforced resin material, for example.

The display unit 13 is capable of swinging relative to the main apparatus 12 around a horizontal axis 19. The horizontal axis 19 is defined in one edge of the main body enclosure 14 in parallel with the flat front surface of the main body enclosure 14. Such a rotation of the display unit 13 enables superposition of the display enclosure 16 on the flat front surface of the main body enclosure 14. The front surface of the display enclosure 16 meets with the front surface of the main body enclosure 14. The mobile phone terminal 11 thus takes a closed attitude. The mobile phone terminal 11 is set in a folded state in this manner.

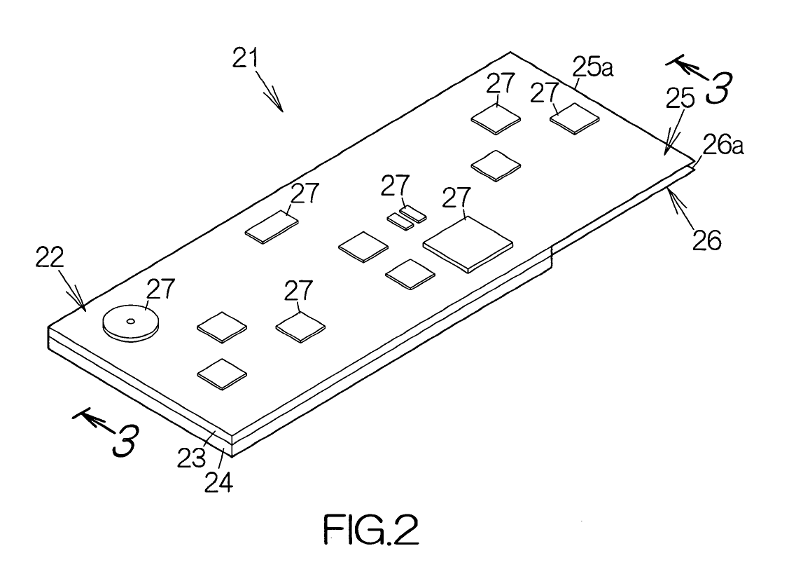

As shown in FIG. 2, a printed circuit board unit 21 includes a rigid substrate 22. The rigid substrate 22 includes first and second rigid insulating layers 23, 24. The first and second rigid insulating layers 23, 24 may have the identical contour. The rigid substrate 22 includes a first flexible printed wiring board 25 partly overlaid on the front surface of the first rigid insulating layer 23, and a second flexible printed wiring board 26 partly overlaid on the back surface of the first rigid insulating layer 23. The second flexible printed wiring board 26 is also overlaid on the front surface of the second rigid insulating layer 24.

The first flexible printed wiring board 25 has a free end 25a located outside the contours of the first and second rigid insulating layers 23, 24. Likewise, the second flexible printed wiring board 26 has a free end 26a located outside the contours of the first and second rigid insulating layers 23, 24. The front surface of the second flexible printed wiring board 26 is opposed to the back surface of the first flexible printed wiring board 25 outside the contours of the first and second rigid insulating layers 23, 24. The first flexible printed wiring board 25 is movable relative to the second flexible printed wiring board 26. Likewise, the second flexible printed wiring board 26 is movable relative to the first flexible printed wiring board 25.

The first rigid insulating layer 23 serves to provide an interval between the first and second flexible printed wiring boards 25, 26. The thickness of the first rigid insulating layer 23 corresponds to the amount of the interval. Electronic components 27 are mounted on the front and back surfaces of the rigid substrate 22, the front and back surfaces of the first flexible printed wiring board 25, and the front and back surfaces of the second flexible printed wiring board 26. Here, the front surface of the rigid substrate 22 corresponds to a part of the front surface of the first flexible printed wiring board 25. The electronic components 27 include CPU chips, memories, resistors, capacitors, microphones, and the like. The electronic components 27, 27 . . . are connected to each other or one another through electrically-conductive patterns formed in the first and second rigid insulating layers 23, 24, and the first and second flexible printed wiring boards 25, 26.

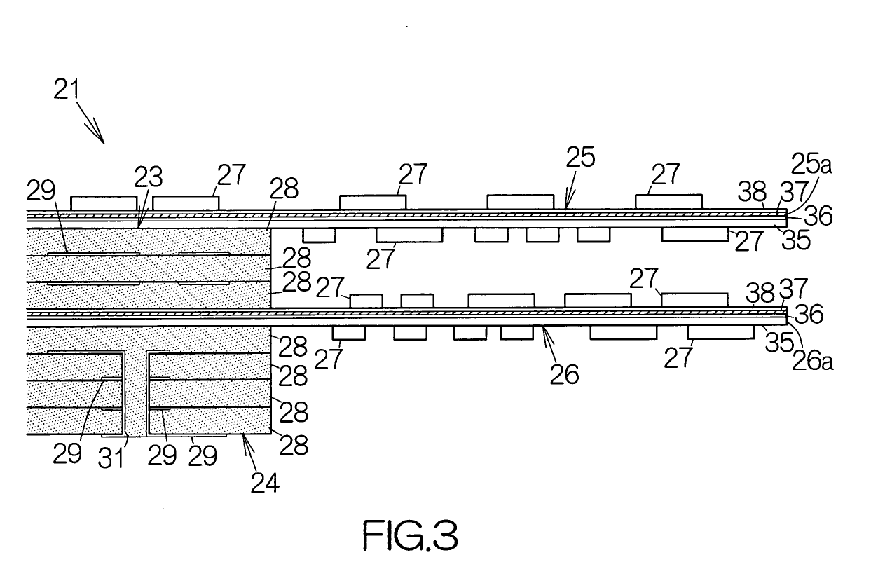

As shown in FIG. 3, the first rigid insulating layer 23 includes three insulating thin plates 28, for example. The second rigid insulating layer 24 includes four insulating thin plates 28, for example. The insulating thin plates 28 may be made of a resin material containing glass fiber cloth, for example. The resin material may be an epoxy resin, for example. Electrically-conductive patterns 29 are located on the front and back surfaces of the insulating thin plates 28. The electrically-conductive patterns 29 may be made of an electrically-conductive material such as copper, for example.

A through-hole via 31 may be formed in the second rigid insulating layer 24, for example. The through-hole via 31 is made of an electrically-conductive material such as copper, for example. An inner space defined in the through-hole via 31 may be filled with a resin material such as an epoxy resin, for example. The electrically-conductive patterns 29 are electrically connected to one another through the through-hole via 31. The through-hole via 31 may also be formed in the first rigid insulating layer 23.

The first and second flexible printed wiring boards 25, 26 each include a metallic thin plate 35 such as an aluminum plate. An insulating layer 36, an electrically-conductive layer 37 and a protection layer 38 are in this sequence overlaid on the metallic thin plate 35. The electrically-conductive layer 37 serves as an electrically-conductive pattern extending on the first flexible printed wiring board 25 or the second flexible printed wiring board 26. The electrically-conductive layer 37 may be made of an electrically-conductive material such as copper, for example. The insulating layer 36 and the protection layer 38 may be made of a resin material such as polyimide resin, for example. The electrically-conductive layer 37 is connected to the electronic components 27. Electric current is supplied to the electronic components 27 through the electrically-conductive patterns 29 and the electrically-conductive layer 37.

The first and second flexible printed wiring boards 25, 26 are partly overlaid on the front and back surfaces of the first rigid insulating layer 23, respectively, in the printed circuit board unit 21. The first and second flexible printed wiring boards 25, 26 extend outside the contours of the first and second rigid insulating layers 23, 24. The first rigid insulating layer 23 serves to ensure an interval between the first and second flexible printed wiring boards 25, 26. The electronic components 27 can be located on the front and back surfaces of the first flexible printed wiring board 25 and the front and back surfaces of the second flexible printed wiring board 26 in addition to the front and back surfaces of the rigid substrate 22. A larger number of the electronic components 27 can be mounted on the printed circuit board unit 21.

Next, a brief description will be made on a method of making the printed circuit board unit 21. Prepregs are first overlaid on the front and back surfaces of a core resin plate. The core resin plate and the prepregs are molded from a resin material containing glass fiber cloth, for example. The resin material may be epoxy resin, for example. The electrically-conductive patterns 29 have already been formed on the surfaces of the core resin plate and the prepregs. A layered mass of the insulating thin plates 28 is formed in this manner. The through-hole via 31 is formed in the layered mass.

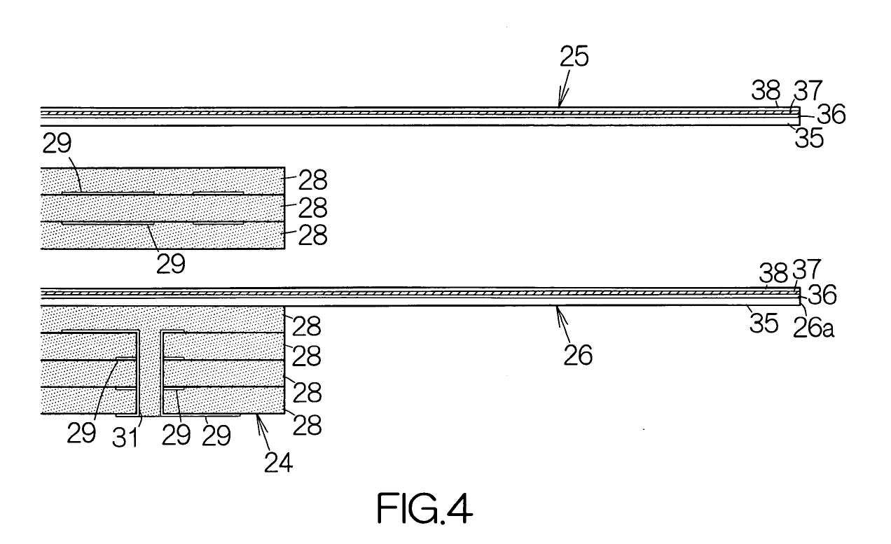

The second flexible printed wiring board 26 is prepared. The electronic components 27 have not yet been mounted on the front and back surfaces of the second flexible printed wiring board 26. A prepreg is utilized to bond the part of the second flexible printed wiring board 26 to the front surface of the layered body of the insulating thin plates 28. In this manner, the second rigid insulating layer 24 is formed as shown in FIG. 4. The second flexible printed wiring board 26 takes a horizontal attitude outside the second rigid insulating layer 24. The second flexible printed wiring board 26 has the free end 26a located outside the contour of the second rigid insulating layer 24.

A core resin plate and prepregs overlaid on the front and back surfaces of the core resin plate are interposed between the first and second flexible printed wiring boards 25, 26. Prepregs serve to bond a part of the first flexible printed wiring board 25 to a part of the second flexible printed wiring board 26. In this manner, the first rigid insulating layer 23 is formed. The first and second flexible printed wiring boards 25, 26 take a horizontal attitude outside the first rigid insulating layer 23. The first flexible printed wiring board 25 has the free end 25a located outside the contour of the first rigid insulating layer 23. The front surface of the second flexible printed wiring board 26 is opposed to the back surface of the first flexible printed wiring board 25 outside the contours of the first and second rigid insulating layers 23, 24.

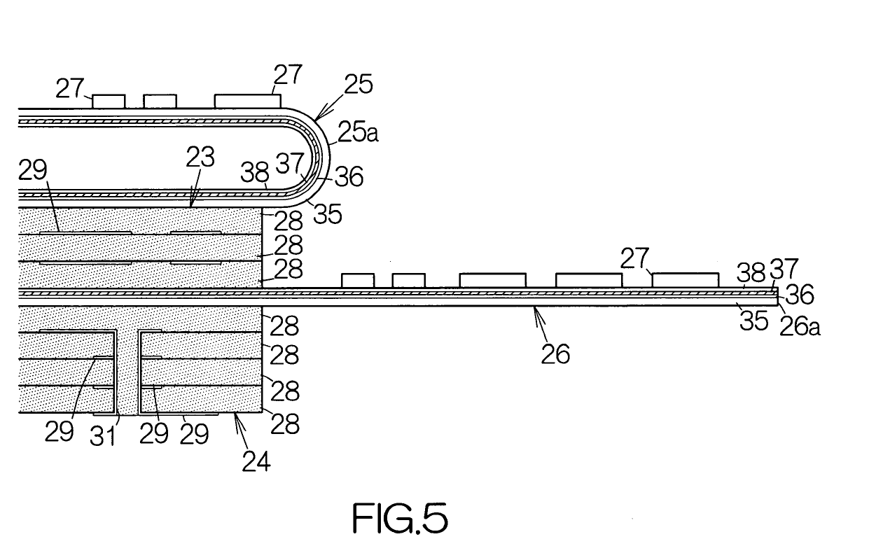

As shown in FIG. 5, the first flexible printed wiring board 25 is turned over from the horizontal attitude outside the first rigid insulating layer 23. The back surface of the first flexible printed wiring board 25 and the front surface of the second flexible printed wiring board 26 are exposed. The electronic components 27 are then mounted on the back surface of the first flexible printed wiring board 25 and the front surface of the second flexible printed wiring board 26. The first flexible printed wiring board 25 is then brought back to the horizontal attitude. The electronic components 27 are then mounted on the front and back surfaces of the rigid substrate 22, on the front surface of the first flexible printed wiring board 25, and on the back surface of the second flexible printed wiring board 26. In this manner, the printed circuit board unit 21 is produced.

The first and second flexible printed wiring boards 25, 26 are movable relative to each other in the printed circuit board unit 21. Specifically, the first and second flexible printed wiring boards 25, 26 are allowed to change their attitude relative to each other, respectively. The first flexible printed wiring board 25 can be turned over so that the electronic components 27 are mounted thereon. The electronic components 27 can thus be mounted on the back surface of the first flexible printed wiring board 25 and the front surface of the second flexible printed wiring board 26 in a relatively facilitated manner. Likewise, the electronic components 27 can be removed from the back surface of the first flexible printed wiring board 25 and the front surface of the second flexible printed wiring board 26 in a relatively facilitated manner. The electronic components 27 can thus be replaced in a relatively facilitated manner.

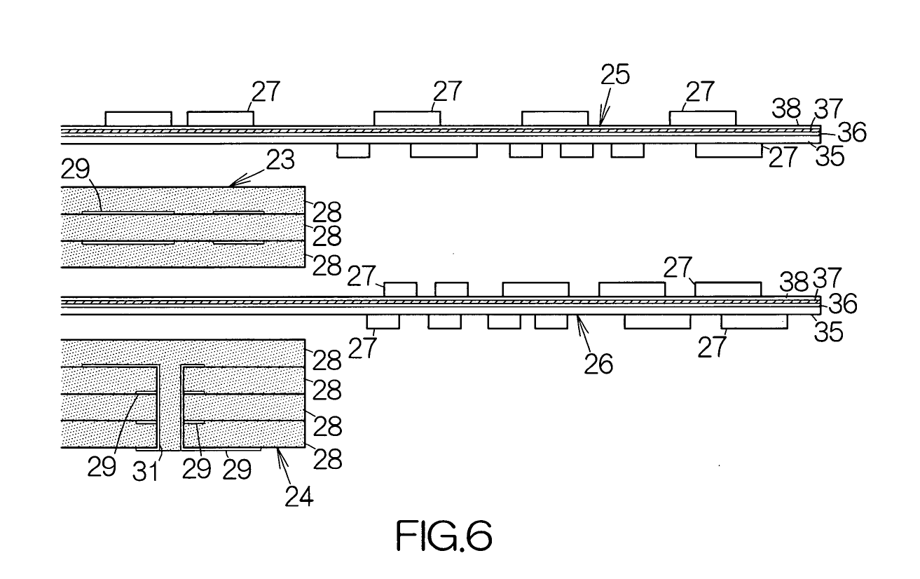

As shown in FIG. 6, for example, the electronic components 27 may be mounted on the front and back surfaces of the first and second flexible printed wiring boards 25, 26 before the first and second flexible printed wiring boards 25, 26 are superposed on the front and back surfaces of the first rigid insulating layer 23 and the front surface of the second rigid insulating layer 24. The first and second flexible printed wiring boards 25, 26 may be superposed on the front and back surfaces of the first rigid insulating layer 23 and the front surface of the second rigid insulating layer 24 outside the mounting areas for the electronic components 27. In this manner, the electronic components 27 can be mounted on the front and back surfaces of the first and second flexible printed wiring boards 25, 26 in a relatively facilitated manner.

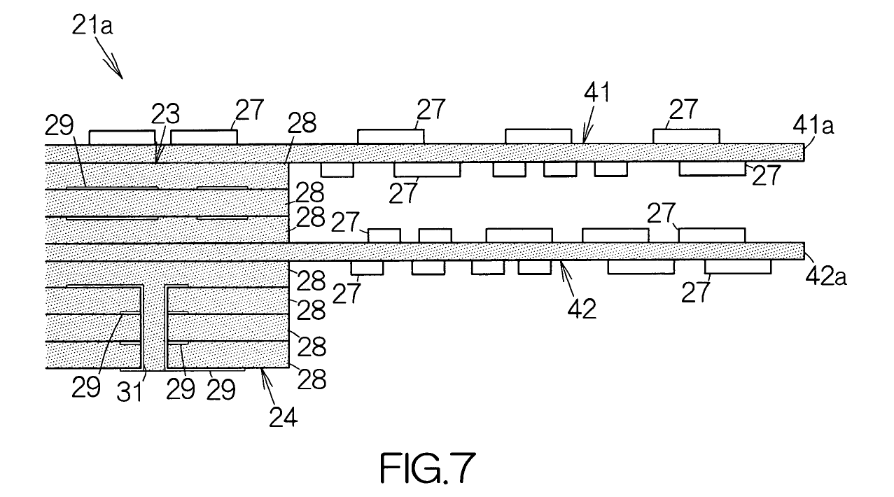

As shown in FIG. 7, a printed circuit board unit 21a may be incorporated in the main body enclosure 14 in place of the aforementioned printed circuit board unit 21. The printed circuit board unit 21a includes first and second auxiliary rigid insulating layers 41, 42 in place of the aforementioned first and second flexible printed wiring boards 25, 26. The contours of the first and second auxiliary rigid insulating layers 41, 42 may be identical to those of the aforementioned first and second flexible printed wiring boards 25, 26. The first and second auxiliary rigid insulating layers 41, 42 have free ends 41a, 42a located outside the contours of the first and second rigid insulating layers 23, 24, respectively.

The first and second auxiliary rigid insulating layers 41, 42 may be made of a resin material containing glass fiber cloth, for example. The resin material may be epoxy resin. The first and second auxiliary rigid insulating layers 41, 42 have a predetermined rigidity. The first and second auxiliary rigid insulating layers 41, 42 are thus prevented from a change in the attitude relative to each other. Electrically-conductive patterns, not shown, may be formed on the front and back surfaces of the first and second auxiliary rigid insulating layers 41, 42. Like reference numerals are attached to the structure or components equivalent to the aforementioned ones.

A larger number of the electronic components 27 can be mounted on the printed circuit board unit 21a in the same manner described above. Core resin plates having different sizes may be bonded together by using prepregs in the production of the printed circuit board unit 21a. Electronic components may be mounted on the core resin plates corresponding to the first and second auxiliary rigid insulating layers 41, 42 prior to the superposition of the core resin plates. The electronic components 27 can thus be mounted on the front and back surfaces of the first and second auxiliary rigid insulating layers 41, 42 in a relatively facilitated manner.

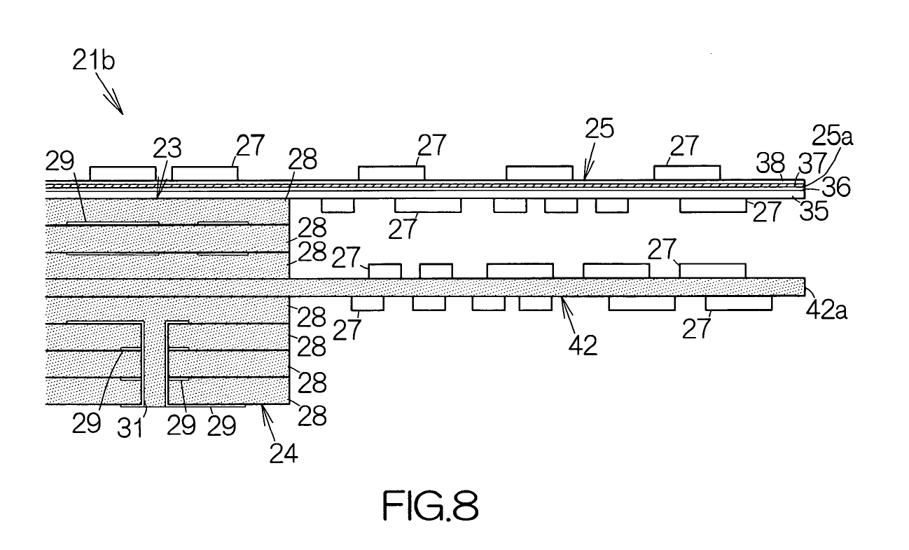

As shown in FIG. 8, a printed circuit board unit 21b may be incorporated in the main body enclosure 14 in place of the aforementioned printed circuit board units 21, 21a. The printed circuit board unit 21b includes a first flexible printed wiring board 25 and the second auxiliary rigid insulating layer 42. The front surface of the second auxiliary rigid insulating layer 42 is opposed to the back surface of the first flexible printed wiring board 25. Like reference numerals are attached to the structure or components equivalent to the aforementioned ones.

A larger number of the electronic components 27 can be mounted on the printed circuit board unit 21b in the same manner as described above. The first flexible printed wiring board 25 can be turned over outside the first rigid insulating layer 23 in the production of the printed circuit board unit 21b. The electronic components 27 can thus be mounted on the back surface of the first flexible printed wiring board 25 and the front surface of the second auxiliary rigid insulating layer 42 in a relatively facilitated manner. Likewise, the electronic components 27 can be removed from the back surface of the first flexible printed wiring board 25 and the front surface of the second auxiliary rigid insulating layer 42 in a relatively facilitated manner. The electronic components 27 can thus be replaced in a relatively facilitated manner.

The printed circuit board units 21, 21a, 21b may be incorporated any electronic apparatus other than the mobile phone terminal 11, such as a notebook personal computer, a personal digital assistant (PDA), or the like. The second rigid insulating layer 24 may be omitted in the printed circuit board units 21, 21a, 21b. A third flexible printed wiring board may be overlaid on the back surface of the second rigid insulating layer 24 in the printed circuit board units 21, 21a, 21b, for example. In this manner, the printed circuit board units 21, 21a, 21b may include two or more flexible printed wiring boards.

The turn of the embodiments is not a showing of the superiority and inferiority of the invention. Although the embodiments of the present inventions have been described in detail, it should be understood that the various changes, substitutions, and alterations could be made hereto without departing from the spirit and scope of the invention.

What is claimed is:

1. A printed wiring board comprising:
a rigid insulating layer;
a first substrate partly overlaid on a front surface of the rigid insulating layer, the first substrate having a free end located outside a contour of the rigid insulating layer; and
a second substrate partly overlaid on a back surface of the rigid insulating layer, the second substrate having a free end located outside the contour of the rigid insulating layer, the second substrate having a front surface opposed to a back surface of the first substrate.

2. The printed wiring board according to claim 1, wherein at least the first substrate is movable relative to the second substrate.

3. A printed circuit board unit comprising:
a rigid insulating layer;
a first substrate partly overlaid on a front surface of the rigid insulating layer, the first substrate having a free end located outside a contour of the rigid insulating layer;
a second substrate partly overlaid on a back surface of the rigid insulating layer, the second substrate having a free end located outside the contour of the rigid insulating layer, the second substrate having a front surface opposed to a back surface of the first substrate; and
a component mounted on at least one of the back surface of the first substrate and the front surface of the second substrate.

4. The printed circuit board unit according to claim 3, wherein at least the first substrate is movable relative to the second substrate.

5. An electronic apparatus including a printed circuit board unit, the printed circuit board unit comprising:
a rigid insulating layer;
a first substrate partly overlaid on a front surface of the rigid insulating layer, the first substrate having a free end outside a contour of the rigid insulating layer;
a second substrate partly overlaid on a back surface of the rigid insulating layer, the second substrate having a free end outside the contour of the rigid insulating layer, the second substrate having a front surface opposed to a back surface of the first substrate; and
a component mounted on at least one of the back surface of the first substrate and the front surface of the second substrate.

6. The electronic apparatus according to claim 5, wherein at least the first substrate is movable relative to the second substrate.
